(19) United States
(12) Patent Application Publication
(10) Pub. No.: US 2010/0051329 A1
(43) Pub. Date: Mar. 4, 2010

(54) PRINTED CIRCUIT BOARD AND METHOD OF MANUFACTURING THE SAME

(75) Inventors: Tae-Hoon KIM, Anyang-si (KR); Dong-Hoon Kim, Seongnam-si (KR); Young-Il Lee, Anyang-si (KR); Sang-Gyun Lee, Suwon-si (KR); Byung-Ho Jun, Seoul (KR); Da-Mi Shim, Suwon-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/429,042

(22) Filed: Apr. 23, 2009

(30) Foreign Application Priority Data
Sep. 4, 2008 (KR) 10-2008-0087277

(51) Int. Cl. H05K 1/03; H05K 3/12; H05K 1/09

(52) U.S. Cl. 174/255; 29/846; 427/96.1; 174/257

(57) ABSTRACT

Disclosed are a printed circuit board and a method of manufacturing the same. The method in accordance with an embodiment of the present invention includes: forming an electroless plated layer on an insulation layer; and forming a circuit pattern by applying conductive ink on the electroless plated layer through an inkjet method.

### CROSS-REFERENCE TO RELATED APPLICATIONS

This application claims the benefit of Korean Patent Application No. 10-2008-0087277, filed with the Korean Intellectual Property Office on Sep. 8, 2008, the disclosure of which is incorporated herein by reference in its entirety.

### BACKGROUND

1. Technical Field

The present invention relates to a printed circuit board and a method of manufacturing the same.

2. Description of the Related Art Recently, much research has been devoted to forming metal wiring of a printed circuit board through an inkjet method. As a result, it has become common to form the wiring of less than 10 micrometers by using the inkjet method.

However, when the metal wiring is formed on an insulation layer by means of such an inkjet method, fine metal wiring can be formed, but it is difficult to obtain adhesive strength between the insulation layer and the metal wiring.

That is, it is relatively easy to bond the same materials, but not easy to bond different materials. Therefore, when the wiring made of metal is formed on the insulation layer such as polyimide, bismaleimide triazine or flame resistant 4 (FR4), there occurs a problem that the metal wiring is exfoliated from the insulation layer because of low adhesive strength between the metal wiring and the insulation layer.

With regard to this matter, an attempt has been made to mix an additive with the ink. However, there are problems that the amount of the additive to be used is limited to a very small amount in order to maintain the electrical conductivity of the wiring, and the additive is difficult to use with a fine nozzle head because of the increased viscosity of the ink. Accordingly, there is a limit in obtaining adhesive strength between the insulation layer and the wiring.

### SUMMARY

The present invention provides a printed circuit board having improved adhesive strength between an insulation layer and a circuit pattern formed by an inkjet method, and provides a method of manufacturing the same.

An aspect of the present invention features a method of manufacturing a printed circuit board. The method in accordance with an embodiment of the present invention includes forming an electroless plated layer on an insulation layer; and forming a circuit pattern by applying conductive ink on the electroless plated layer through an inkjet method.

The method can further include, before the forming of the electroless plated layer, surface treating the insulation layer such that an adhesive strength is increased between the insulation layer and the electroless plated layer.

The method can further include, after the forming of the circuit pattern, forming an electroless plated pattern by removing an exposed part of the electroless plated layer through flash etching.

Another aspect of the present invention features a printed circuit board. The printed circuit board in accordance with an embodiment of the present invention can include an insulation layer; an electroless plated pattern being formed on the insulation layer; and a circuit pattern being formed by applying conductive ink on the electroless plated pattern through an inkjet method.

The insulation layer can be surface treated such that adhesive strength between the electroless plated pattern and the insulation layer is increased.

The circuit pattern can be made of at least any one of nickel (Ni), copper (Cu), silver (Ag), tin (Sn) and gold (Au).

### BRIEF DESCRIPTION OF THE DRAWINGS

FIG. 1 is a flowchart showing a method of manufacturing a printed circuit board in accordance with an aspect of the present invention.

FIGS. 2 through 6 are cross sectional views showing each process of a method of manufacturing a printed circuit board in accordance with an aspect of the present invention.

FIG. 7 is a cross sectional view showing an embodiment of a printed circuit board in accordance with another aspect of the present invention.

### DETAILED DESCRIPTION

Hereinafter, embodiments of a printed circuit board and a manufacturing method thereof in accordance with the present invention will be described in detail with reference to the accompanying drawings. In description with reference to accompanying drawings, the same reference numerals will be assigned to the same or corresponding elements, and repetitive descriptions thereof will be omitted.

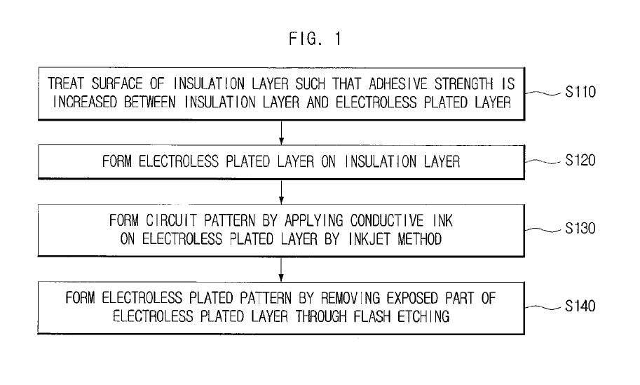

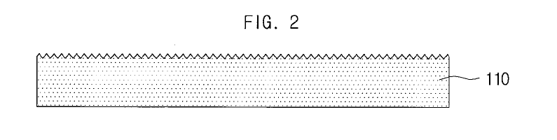

FIG. 1 is a flowchart showing a method of manufacturing a printed circuit board 100 in accordance with an aspect of the present invention. FIGS. 2 through 6 are cross sectional views showing each process of a method of manufacturing a printed circuit board 100 in accordance with an aspect of the present invention.

According to an embodiment of the present invention, after an electroless plated layer 120 is formed on an insulation layer 110, a circuit pattern 150 is formed by applying conductive ink 140 on the electroless plated layer 120 through an inkjet method. As a result, provided is a method of manufacturing a printed circuit board 100 capable of improving adhesive strength between the insulation layer 110 and the circuit pattern 150.

Hereinafter, each of processes will be described in detail with reference to FIGS. 2 through 6.

First, as shown in FIG. 2, a surface treatment is performed on an insulation layer 110 such that adhesive strength is increased between the insulation layer 110 and an electroless plated layer 120 (S110). That is, before the electroless plated layer 120 is formed on the insulation layer 110, the surface treatment is performed on one surface of the insulation layer 110, on which the electroless plated layer 120 is to be formed in order to improve the adhesive strength between the insulation layer 110 and the electroless plated layer 120.

In this case, as shown in FIG. 2, roughening treatment can be performed as a surface treatment. Here, the roughening treatment increases the surface roughness of the insulation layer 110. The surface area of the insulation layer 110 is hereby increased, so that the adhesive strength between the insulation layer 110 and the electroless plated layer 120 is increased.

The surface treatment can be variously performed by physical or chemical methods as well as the roughening treatment. For example, ion-beam treatment or coating treatment with chemical substances and the like can be performed.

Here, the ion-beam treatment is a process of forming a hydrophilic functional group by providing reactive gas after irradiating an inert ion on the surface of the insulation layer. Through the ion-beam treatment, the surface of the insulation layer obtains hydrophilic property, and the adhesive strength between the insulation layer and the electroless plated layer is increased.

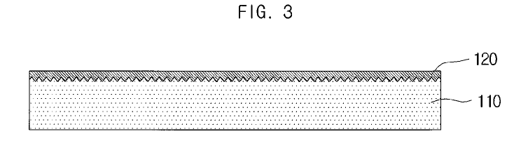

As shown in FIG. 3, the electroless plated layer 120 is formed on the insulation layer 110 (S120). That is, the electroless plated layer 120 is formed by chemical plating on the insulation layer 110 having a roughening treated surface. Here, the electroless plated layer 120 can be made of nickel (Ni), copper (Cu), silver (Ag), tin (Sn) and gold (Au) which have excellent adhesive strength to a circuit pattern 150 or a material formed through any combination of at least two of them.

As such, since the electroless plated layer 120 is formed before forming the circuit pattern 150, the circuit pattern 150 to be formed by using the inkjet method is adhered to the electroless plated layer 120 made of a metal material. Accordingly, the adhesive strength between the insulation layer 110 and the circuit pattern 150 can be remarkably improved as compared with the adhesive strength at the time of directly printing the circuit pattern 150 on the insulation layer of a different material.

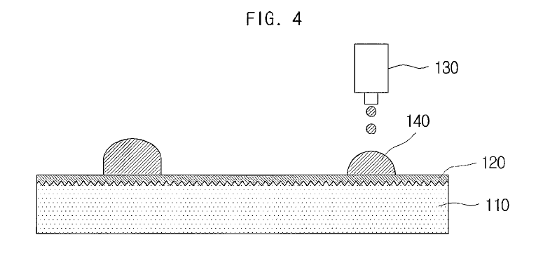

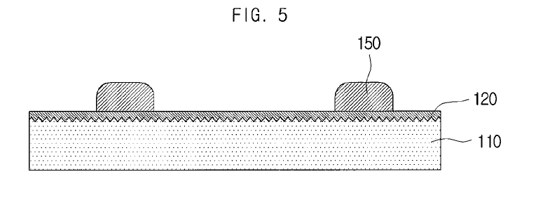

In the next step, as shown in FIGS. 4 and 5, the circuit pattern 150 is formed by applying the conductive ink 140 on the electroless plated layer 120 by the inkjet method (S130). The forming of the circuit pattern 150 can be described stage by stage as follows.

First, as shown in FIG. 4, the conductive ink 140 made of metal nanoparticles is discharged from the inkjet head 130 and the conductive ink 140 is applied on the electroless plated layer 120. As a result, a droplet of the conductive ink 140 is formed on a position corresponding to the position of the circuit pattern 150.

Here, the conductive ink 140 is, identically to the electroless plated layer 120, made of nickel (Ni), copper (Cu), silver (Ag), tin (Sn) and gold (Au) or a material formed through any combination of at least two of them. The conductive ink 140 can have a shape of a nanoparticle, an organic compound or an ion.

Subsequently, as shown in FIG. 5, the circuit pattern 150 is formed by drying and sintering the droplet of the conductive ink 140. As a result, metal nanoparticles of the droplet of the conductive ink 140 are not only adhered to one another but are also firmly adhered to the electroless plated layer 120.

As such, since the circuit pattern 150 is formed on the electroless plated layer 120 by the inkjet method, the circuit pattern 150 made of a metal material is adhered to the electroless plated layer 120 made of a metal material. Accordingly, the adhesive strength between the insulation layer 110 and the circuit pattern 150 can be remarkably improved as compared with the adhesive strength at the time of directly printing the circuit pattern on the insulation layer made of different material.

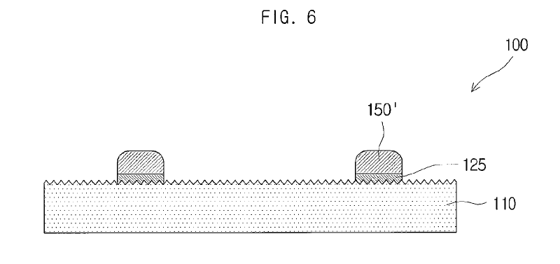

As shown in FIG. 6, an electroless plated pattern 125 is formed by removing the exposed part of the electroless plated layer (see reference numeral 120 of FIG. 5) through a flash etching (S140). In order to prevent a short-cut of the circuit pattern 150, the exposed part of the electroless plated layer (see reference numeral 120 of FIG. 5) is removed by means of the flash etching, excluding the part of the electroless plated layer (see reference numeral 120 of FIG. 5) on which the circuit patterns 150 are formed. Accordingly, only the electroless plated pattern 125 corresponding to the circuit pattern remains on the insulation layer 110.

However, the part of the circuit pattern 150 is removed together with the electroless plated layer (see reference numeral 120 of FIG. 5) through such a flash etching, the removed amount of a circuit pattern 150′ is not influential on the entire thickness of the circuit pattern 150′ because the circuit pattern 150 is greatly thicker than the electroless plated layer (see reference numeral 120 of FIG. 5) is.

Hereinafter, a printed circuit board is manufactured by manufacturing methods in accordance with both the prior art and the embodiment of the present invention. In each case mentioned above, experimental results of the adhesive strength between the insulation layer and the circuit pattern will be described.

### EXPERIMENTAL EXAMPLE

First, after roughness treatment is performed on the insulation layer 110 made of bismaleimide triazine, the electroless plated layer 120 made of silver (Ag) is formed to have a thickness of 3 micrometers on the insulation layer 110.

Then, the conductive ink 140 made of silver (Ag) nanoparticles is applied on the electroless plated layer 120 by using the inkjet head 130. Then, the circuit pattern 150 is formed to have a thickness of 20 micrometers by drying and sintering the applied conductive ink 140.

Then, the exposed part of the electroless plated layer 120 and a part of the circuit pattern 150 are removed by the flash etching. Consequently, the circuit pattern 150′ has a thickness of 16 micrometers.

If the adhesive strength between the circuit pattern 150′ and the insulation layer 110 is tested by using an adhesive tape having an adhesive strength of 4819 g/in, it can be understood that the circuit pattern 150′ remains on the insulation layer 110 without being exfoliated.

### COMPARISON EXAMPLE

According to a method of manufacturing the printed circuit pattern by using the conventional inkjet method, a circuit pattern is formed by applying the conductive ink made of copper (Cu) nanoparticles on the insulation layer made of bismaleimide triazine.

Similarly to the described embodiment, if the adhesive strength between the circuit pattern and the insulation layer is tested by using an adhesive tape having an adhesive strength of 4819 g/in, it can be understood that the circuit patterns are largely exfoliated.

As shown in the described experimental example and the comparison example, the method of manufacturing a printed circuit board according to the conventional technology causes exfoliation of the circuit pattern due to the weak adhesive strength between the circuit pattern and the insulation layer. On the other hand, the method of manufacturing a printed circuit board according to the embodiment of the present invention can prevent the circuit pattern 150′ from being exfoliated because the circuit pattern 150′ is firmly adhered to the insulation layer 110 through the electroless plated pattern 125.

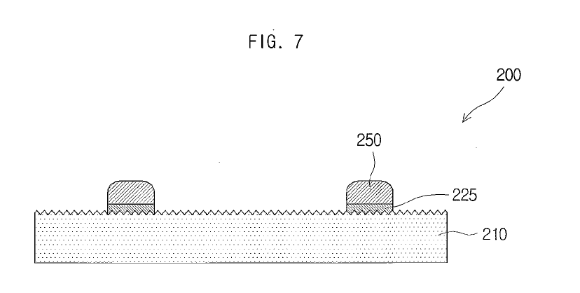

In the next step, a printed circuit board 200 according to another aspect of the present invention will be described with reference to FIG. 7.

FIG. 7 is a cross sectional view showing an embodiment of a printed circuit board 200 in accordance with another aspect of the present invention.

According to the embodiment of the present invention, provided is a printed circuit board 200 including an insulation layer 210, an electroless plated pattern 225 formed on the insulation layer 210, a circuit pattern 250 formed by applying conductive ink on the electroless plated pattern 225 through an inkjet method.

According to such an embodiment of the present invention, since the circuit pattern 250 is not exfoliated thanks to increased adhesive strength between the circuit pattern 250 and the insulation layer 210, it is possible to implement the printed circuit board 200 capable of more stably and effectively to transmit an electrical signal.

Hereinafter, respective components will be described in detail with reference to FIG. 7.

The insulation layer 210, for example, can be made of bismaleimide triazine, polyimide, flame resistant 4 (FR4) or any combination of at least two of them. A surface treatment is performed on the insulation layer in order to increase an adhesive strength between the insulation layer 210 and the electroless plated pattern 225 formed on the insulation layer 210. That is, as shown in FIG. 7, the insulation layer 210 is roughening treated and the surface roughness of the insulation layer is increased. As a result, the surface area of the insulation layer 210 is increased, so that the adhesive strength between the insulation layer 210 and the electroless plated pattern 225 is increased.

The insulation layer 210 can be surface treated by physical or chemical methods as well as the described roughening treatment. For example, ion-beam treatment or coating treatment with chemical substances and the like can be performed. Since the matter described above has been described in detail in an embodiment of the method of manufacturing a printed circuit board of the present invention, the description thereof will be omitted.

The electroless plated pattern 225 is formed on the insulation layer 210. In other words, as shown in FIG. 7, the electroless plated pattern 225 is formed on the roughening treated surface of the insulation layer 210 by chemical plating. The electroless plated pattern 225 can be made of nickel (Ni), copper (Cu), silver (Ag), tin (Sn) and gold (Au) which have excellent adhesive strength to a circuit pattern 250 or a material formed through any combination of at least two of them.

After forming the electroless plated layer (see reference numeral 120 of FIG. 3) on the insulation layer 210, the electroless plated pattern 225 can be formed by removing the exposed part of the electroless plated layer by means of the flash etching, excluding the part of the electroless plated layer on which the circuit patterns 250 have been formed. Since the matter described above has been described in detail in an embodiment of the method of manufacturing a printed circuit board of the present invention, the description thereof will be omitted.

The circuit pattern 250 formed by applying conductive ink on the electroless plated pattern 225 through the inkjet method. The circuit pattern 250, identically to the electroless plated pattern 225, can be made of nickel (Ni), copper (Cu), silver (Ag), tin (Sn) and gold (Au) or a material formed through any combination of at least two of them. That is, since the conductive ink is made of metal nanoparticles, the circuit pattern 250 has a shape in which the metal nanoparticles are not only bonded with one another but are also firmly adhered to the electroless plated pattern 225.

After applying the conductive ink on the electroless plated layer (see reference numeral 120 of FIG. 3) and then drying and sintering the applied conductive ink, such a circuit pattern 250 is formed by removing a part of the electroless plated layer during the process of forming the electroless plated pattern 225 by means of the described flash etching.

However, the part of the circuit pattern 250 is removed together with the electroless plated layer (see reference numeral 120 of FIG. 3) through such a flash etching, the removed amount of a circuit pattern 250 is not influential on the entire thickness of the circuit pattern 250 because the circuit pattern 250 is greatly thicker than the electroless plated layer (see reference numeral 120 of FIG. 3) is. Since the matter described above has been described in detail in an embodiment of the method of manufacturing a printed circuit board of the present invention, the description thereof will be omitted.

As such, since the circuit pattern 250 is formed on the electroless plated pattern 225 by the inkjet method, the circuit pattern 250 made of a metal material is adhered to the electroless plated pattern 225 made of a metal material. Accordingly, the adhesive strength between the insulation layer 210 and the circuit pattern 250 can be remarkably improved as compared with the adhesive strength at the time of directly printing the circuit pattern 250 on the insulation layer 210 made of different material.

Such an improvement of the adhesive strength is also clearly shown through the experimental example and the comparison example described in an embodiment of the method of manufacturing a printed circuit board of the present invention. Since the matter described above has been described in detail in an embodiment of the method of manufacturing a printed circuit board of the present invention, the description thereof will be omitted.

While the one embodiment of the present invention has been described, it is possible for those skilled in the art to make various changes and modifications of the forms and details of the present invention by means of addition, change, elimination or supplement, etc., of the components of the present invention without departing from the spirit of the present invention as defined by the appended claims, which also belongs to the scope of rights of the present invention.

What is claimed is:

1. A method of manufacturing a printed circuit board, the method comprising:
forming an electroless plated layer on an insulation layer; and
forming a circuit pattern by applying conductive ink on the electroless plated layer through an inkjet method.

2. The method of claim 1, further comprising, before the forming of the electroless plated layer, surface treating the insulation layer such that an adhesive strength is increased between the insulation layer and the electroless plated layer.

3. The method of claim 1, further comprising, after the forming of the circuit pattern, forming an electroless plated pattern by removing an exposed part of the electroless plated layer through flash etching.

4. A printed circuit board comprising:
an insulation layer;
an electroless plated pattern being formed on the insulation layer; and
a circuit pattern being formed by applying conductive ink on the electroless plated pattern through an inkjet method.

5. The printed circuit board of claim 4, wherein the insulation layer is surface treated such that adhesive strength between the electroless plated pattern and the insulation layer is increased.

6. The printed circuit board of claim 4, wherein the circuit pattern is made of at least any one selected from a group consisting of nickel (Ni), copper (Cu), silver (Ag), tin (Sn) and gold (Au).

7. The printed circuit board of claim 4, wherein the insulation layer is made of at least any one selected from a group consisting of bismaleimide triazine, polyimide and flame resistant 4 (FR4).
